(19) United States
(12) Patent Application Publication
(10) Pub. No.: US 2018/0346639 A1
(43) Pub. Date: Dec. 6, 2018

(54) Epoxy resin, method for producing the epoxy resin, curable resin composition, and cured product thereof

(71) Applicant: DIC Corporation, Tokyo (JP)

(72) Inventors: Yousuke Hirota, Ichihara-shi (JP); Yoshiyuki Takahashi, Ichihara-shi (JP); Ayumi Takahashi, Ichihara-shi (JP)

(73) Assignees: DIC Corporation, Tokyo (JP); DIC Corporation, Tokyo (JP)

(21) Appl. No.: 15/781,261

(22) PCT Filed: Nov. 17, 2016
(86) PCT No.: PCT/JP2016/084053

§ 371 Date: Jun. 4, 2018

(30) Foreign Application Priority Data
Dec. 8, 2015 (JP) 2015-239358

(51) Int. Cl. C08G 59/06; C08J 5/24; C08J 5/04; C09J 163/00; C09J 7/20; H05K 1/03

(52) U.S. Cl. CPC C08G 59/06; C08J 5/24; H05K 1/0353; C09J 163/00; C09J 7/20; C08J 5/04

(57) ABSTRACT

Provided are an epoxy resin which has high fluidity, a method for producing the epoxy resin, a cured product thereof, and a use thereof. The epoxy resin is represented by the structural formula (1) below and exhibits a peak P appearing between peaks with n=0 and n=1 in a GPC measurement in which the area of the peak P is 0.0100 to 0.0750 times the area of the peak with n=0,

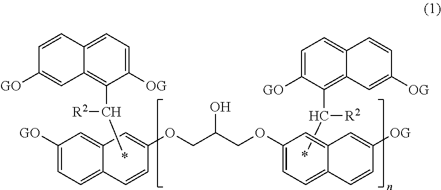

wherein G represents a glycidyl group, R¹ represents a hydrogen atom, an alkyl group having 1 to 4 carbon atoms, a phenyl group, a hydroxyphenyl group, or a halogen-substituted phenyl group, symbol * indicates bonding to any of the carbon atoms capable of forming a bond on the naphthalene ring, and n represents the number of repeats and is 0 to 10 on average.

### TECHNICAL FIELD

The present invention relates to an epoxy resin which is advantageous not only in that the epoxy resin has high fluidity, but also in that a cured product obtained therefrom has excellent heat resistance and high-temperature stability, a method for producing the epoxy resin, a curable resin composition containing the epoxy resin, a cured product thereof, and a use thereof.

### BACKGROUND ART

Epoxy resins are used in adhesives, molding materials, and coating materials, and further cured products of the epoxy resins have excellent heat resistance and moisture resistance, and therefore the epoxy resins are widely used in the electric and electronic fields, such as semiconductor encapsulating materials and insulating materials for printed wiring board.

In the above fields, power semiconductors, such as a car power module, are important key technology to achieve energy saving in electric and electronic devices, and, as the power semiconductors are further increased in current, reduced in size, and improved in efficiency, a switch from a conventional silicon (Si) semiconductor to a silicon carbide (SiC) semiconductor is progressing. The SiC semiconductor has an advantage in that it can operate under conditions at higher temperatures, and therefore the semiconductor encapsulating material used in the SiC semiconductor is required to have even higher heat resistance. In addition, important performance required for the semiconductor encapsulating material includes high fluidity, and high-temperature stability such that the material suffers a less change in the mass even when exposed to high temperatures for a long time, and a resin material having both of these performances is desired.

For meeting these various required properties, for example, the use of 1,1-bis(2,7-diglycidyloxy-1-naphthyl)methane as a semiconductor encapsulating material is provided (see, for example, PTL 1). The compound provided in the PTL 1 is produced using 2,7-dihydroxynaphthalene, formaldehyde, and an epihalohydrin. A cured product obtained from the epoxy resin produced by such a method exhibits excellent heat resistance; however, the epoxy resin has a high melt viscosity, and hence satisfactory fluidity for a curable resin composition or a semiconductor encapsulating material is difficult to obtain, and further the cured product cannot achieve the high-temperature stability at a practical level.

For obtaining a curable resin composition having more excellent fluidity, the use of a reaction product of a 1,1-bis(2,7-dihydroxynaphthyl)alkane and an epihalohydrin, and a difunctional epoxy resin in combination is provided (see, for example, PTL 2). However, a cured product obtained from the above-mentioned resin composition provided in the PTL 2 cannot achieve a satisfactory heat resistance in the above-mentioned uses.

### CITATION LIST

### Patent Literature

### PTL 1: JP-A-4-217675

### PTL 2: JP-A-2000-103941

### SUMMARY OF INVENTION

### Technical Problem

In view of the above, a task to be achieved by the present invention is to provide an epoxy resin which is advantageous not only in that the epoxy resin has high fluidity, but also in that a cured product obtained therefrom has excellent heat resistance and high-temperature stability, a method for producing the epoxy resin, a curable resin composition containing the epoxy resin, a cured product thereof, and uses thereof.

### Solution to Problem

The present inventors have conducted extensive and intensive studies. As a result, it has been found that the above-mentioned task can be achieved by using an epoxy resin which is represented by the structural formula (1) below and exhibits a peak P appearing between peaks with n=0 and n=1 in a GPC measurement in which there is a predetermined ratio between the area of the peak P and the area of the peak with n=0, and the present invention has been completed.

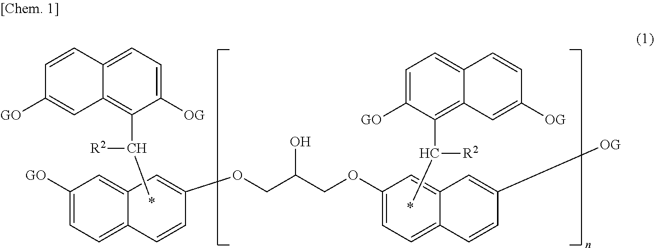

In the structural formula (1), G represents a glycidyl group, R¹ each independently represents a hydrogen atom, an alkyl group having 1 to 4 carbon atoms, a phenyl group, a hydroxyphenyl group, or a halogen-substituted phenyl group, symbol * indicates bonding to any of carbon atoms capable of forming a bond on the naphthalene ring, and n represents the number of repeats.

Specifically, the present invention provides an epoxy resin which is represented by the following structural formula (1):

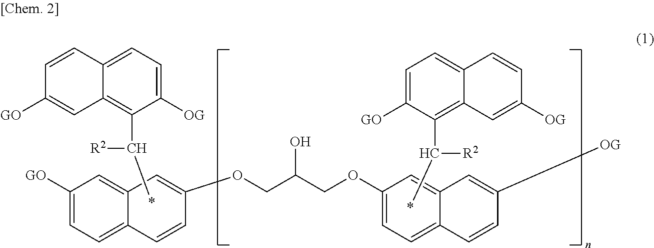

wherein, G represents a glycidyl group, R¹ each independently represents a hydrogen atom, an alkyl group having 1 to 4 carbon atoms, a phenyl group, a hydroxyphenyl group, or a halogen-substituted phenyl group, symbol * indicates bonding to any of carbon atoms capable of forming a bond on the naphthalene ring, and n represents the number of repeats and is 0 to 10 on average, and exhibits a peak P appearing between peaks with n=0 and n=1 in a GPC measurement in which the area of the peak P is 0.0100 to 0.0750 times the area of the peak with n=0, and the present invention also provides a method for producing the same, a curable resin composition containing the same, a cured product, and uses thereof.

### Advantageous Effects of Invention

In the invention, there can be provided an epoxy resin which is advantageous not only in that the epoxy resin has high fluidity, but also in that a cured product obtained therefrom has excellent heat resistance and high-temperature stability, a method for producing the epoxy resin, a curable resin composition, a cured product thereof, and a semiconductor encapsulating material, a semiconductor device, a prepreg, a circuit board, a buildup film, a buildup substrate, a fiber-reinforced composite material, and a fiber-reinforced molded article, each using the above epoxy resin or the like.

### BRIEF DESCRIPTION OF DRAWINGS

FIG. 1 is a GPC chart of the epoxide (I) synthesized in Example 1.

FIG. 2 is a GPC chart of the crystalline epoxy resin (A-1) obtained in Example 1.

FIG. 3 is a GPC chart of the crystalline epoxy resin (A-2) obtained in Example 2.

FIG. 4 is a GPC chart of the crystalline epoxy resin (A-3) obtained in Example 3.

### DESCRIPTION OF EMBODIMENTS

### <Epoxy Resin>

Hereinbelow, the epoxy resin of the present invention will be described in detail.

The epoxy resin of the invention is an epoxy resin which is represented by the following structural formula (1):

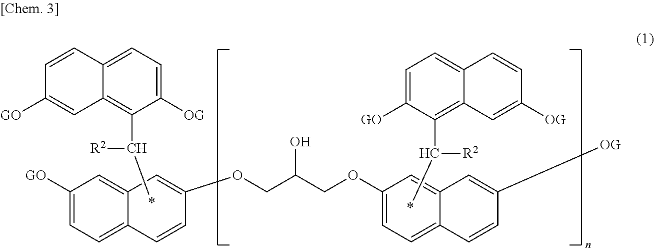

wherein G represents a glycidyl group, R¹ each independently represents a hydrogen atom, an alkyl group having 1 to 4 carbon atoms, a phenyl group, a hydroxyphenyl group, or a halogen-substituted phenyl group, symbol * indicates bonding to any of carbon atoms capable of forming a bond on the naphthalene ring, and n represents the number of repeats and is 0 to 10 on average, and

exhibits a peak P appearing between peaks with n=0 and n=1 in a GPC measurement in which the area of the peak P is 0.0100 to 0.0750 times the area of the peak with n=0.

Any of the carbon atoms on the naphthalene ring which are capable of having a substituent bonded thereto means a carbon atom on the naphthalene ring at any of the 1-position, 3-position, 4-position, 5-position, 6-position, and 8-position.

In the above-described compound, from the viewpoint of obtaining a cured product which has excellent high-temperature stability and can exhibit high heat resistance, R¹ is preferably a hydrogen atom.

In the structural formula (1) above, from the viewpoint of the fluidity and crystallinity, the average of the number n of repeats is 0.01 to 5.00, preferably 0.05 to 4.00. The average is determined by making a calculation from the measurements by the below-mentioned GPC.

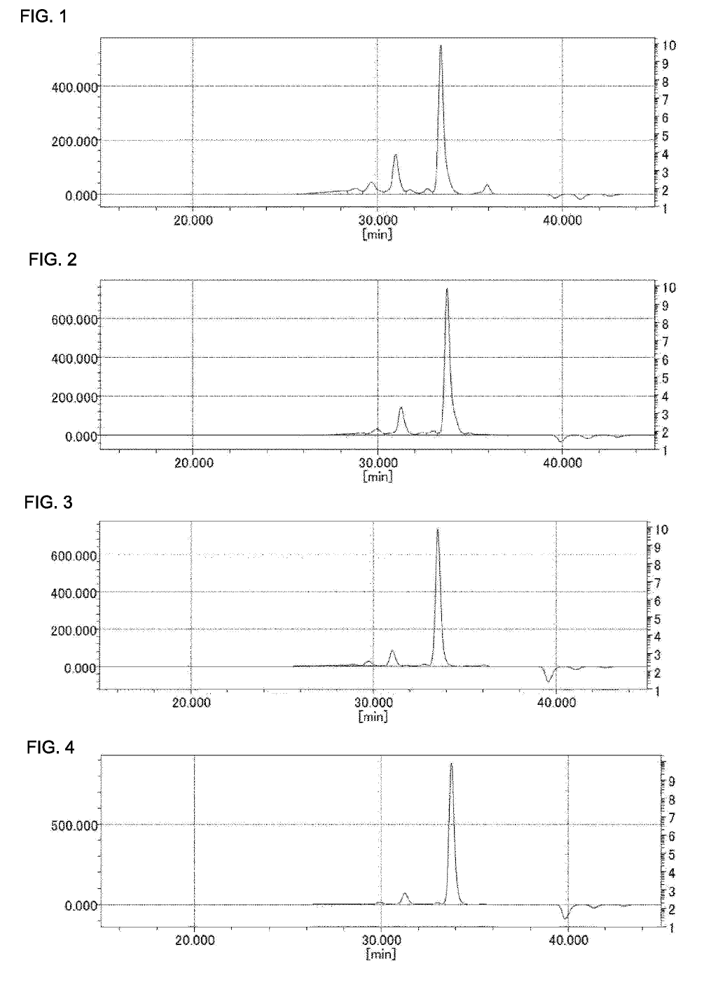

In a gel permeation chromatography (GPC) measurement, as shown in FIG. 1, the epoxy resin of the invention has a peak (hereinafter, referred to as a “peak P”) between peaks with n=0 (tetra-functional) and n=1 (hexa-functional). In FIG. 1, a peak with n=1 appears at a retention time (RT: abscissa) of 31 to 31.5 minutes, a peak with n=0 appears at a retention time of 33 to 34 minutes, and the peak P appears between these peaks. Generally, it has been known that the use of a high purity compound improves physical properties. In the invention, the epoxy resin represented by the structural formula (1) above has, in a GPC measurement, a peak P between peaks with n=0 and n=1, wherein the area of the peak P is 0.0100 to 0.0750 times, further preferably 0.0120 to 0.0700 times the area of the peak with n=0, and thus the epoxy resin is advantageous not only in that the epoxy resin has high fluidity, but also in that a cured product obtained therefrom has excellent heat resistance and high-temperature stability. When the area of the peak P is less than 0.0100 times the area of the peak with n=0, the epoxy resin has so high crystallinity that a composition being prepared using the epoxy resin is likely to suffer a problem. Conversely, when the area of the peak P is more than 0.0750 times the area of the peak with n=0, a problem in that the heat resistance and high-temperature stability are unsatisfactory is likely to occur.

Further, from the viewpoint of facilitating production of a cured product having more excellent high-temperature stability, the % by area of the peak P in a GPC measurement is preferably in the range of from 0.5 to 4.5% by area, more preferably in the range of from 1.0 to 4.4% by area.

With respect to the peak P, % by area can be measured under the below-shown conditions for GPC measurement.

### <Conditions for GPC Measurement>

Measuring apparatus: “HLC-8320 GPC”, manufactured by Tosoh Corp.
Columns: Guard column “HXL-L”, manufactured by Tosoh Corp.
+ “TSK-GEL G2000HXL”, manufactured by Tosoh Corp.
+ “TSK-GEL G2000HXL”, manufactured by Tosoh Corp.
+ “TSK-GEL G3000HXL”, manufactured by Tosoh Corp.
+ “TSK-GEL G4000HXL”, manufactured by Tosoh Corp.
   Detector: RI (Differential refractometer)
   Data processing: “GPC Workstation EcoSEC-WorkStation”, manufactured by Tosoh Corp.

### Conditions for Measurement:

Column temperature: 40° C.

Developing solvent: Tetrahydrofuran

Flow rate: 1.0 ml/minute

Standard: In accordance with the measurement manual of the above-mentioned “GPC Workstation EcoSEC-WorkStation”, the monodispersed polystyrenes having known molecular weights shown below were used.

### (Polystyrenes Used)

“A-500”, manufactured by Tosoh Corp.

“A-1000”, manufactured by Tosoh Corp.

“A-2500”, manufactured by Tosoh Corp.

“A-5000”, manufactured by Tosoh Corp.

“F-1”, manufactured by Tosoh Corp.

“F-2”, manufactured by Tosoh Corp.

“F-4”, manufactured by Tosoh Corp.

“F-10”, manufactured by Tosoh Corp.

“F-20”, manufactured by Tosoh Corp.

“F-40”, manufactured by Tosoh Corp.

“F-80”, manufactured by Tosoh Corp.

“F-128”, manufactured by Tosoh Corp.

Sample: A 1.0% by mass tetrahydrofuran solution, in terms of a resin solids content, which has been subjected to filtration using a microfilter (50 μl).

The compound corresponding to the peak P is presumed to be a mixture of compounds containing a dimer of dihydroxynaphthalene. The peak P includes compounds which are represented by the structural formulae (1-1) and (1-2) below, and which are formed during a reaction with epichlorohydrin, which is a preferred method for producing an epoxy resin in the invention, and the epoxy resin represented by the structural formula (1) above, in which the bond is partially broken, and the like.

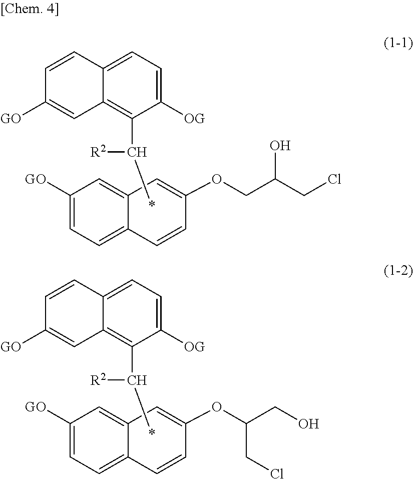

With respect to the epoxy resin of the invention, from the viewpoint of obtaining a cured product which suffers a less change in the mass even when exposed to high temperatures for a long time, i.e., a cured product having more excellent high-temperature stability, the epoxy equivalent of the epoxy resin is preferably in the range of from 140 to 160 g/eq, more preferably in the range of from 143 to 158 g/eq.

Further, with respect to the epoxy resin of the invention, from the viewpoint of achieving further excellent operating properties when producing a curable resin composition such that the epoxy resin can be a material suitable for, for example, a semiconductor encapsulating material for use in a surface mount semiconductor device, particularly suitable for the use of a semiconductor encapsulating material for transfer molding, the melt viscosity of the epoxy resin at 150° C., as measured in accordance with ASTM D4287, is preferably in the range of from 1.0 to 3.5 dPa·s.

### <Method for Producing an Epoxy Resin>

The method for producing an epoxy resin of the invention is characterized in that the method comprises subjecting, to recrystallization, an epoxide of a phenol compound represented by the following structural formula (2):

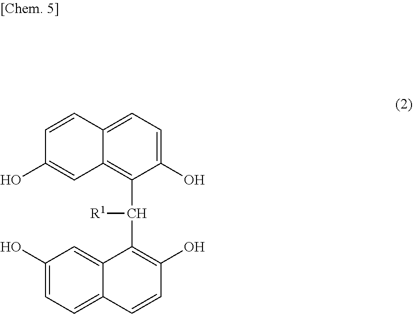

wherein R¹ each independently represents a hydrogen atom, an alkyl group having 1 to 4 carbon atoms, a phenyl group, a hydroxyphenyl group, or a halogen-substituted phenyl group, so that the above-mentioned epoxy resin of the invention can be advantageously obtained.

### <Step 1>

In the method for producing an epoxy resin of the invention, the step 1 is an epoxidation step for a phenol compound, and a general epoxidation reaction method can be applied, except for the use of the phenol compound represented by the structural formula (2) above. Specifically, for example, there can be mentioned a method in which 1 to 10 mol of an epihalohydrin is added to 1 mol of the phenol compound represented by the structural formula (2) above, and further 0.9 to 2.0 mol of a basic catalyst is added at one time or slowly added to 1 mol of the compound represented by the structural formula (2) above, and a reaction is conducted at a temperature of 20 to 120° C. for 0.5 to 10 hours. The basic catalyst may be used in a solid form or in the form of an aqueous solution thereof. When an aqueous solution of the basic catalyst is used, a method may be employed in which the aqueous solution is continuously added, whereupon water and an epihalohydrin are continuously distilled off from the reaction mixture under a reduced pressure or under atmospheric pressure, and further subjected to separation to remove water and the epihalohydrin is allowed to continuously go back into the reaction mixture.

When an industrial production is performed, all the epihalohydrin charged into the first batch for the production in the epoxidation step is a fresh epihalohydrin, but, in the subsequent batches, it is preferred that the epihalohydrin recovered from the crude reaction product and a fresh epihalohydrin in an amount corresponding to the amount of the epihalohydrin consumed in the reaction are used in combination. In this instance, an impurity derived from the reaction of epichlorohydrin, water, an organic solvent, and the like, such as glycidol, may be contained. With respect to the epihalohydrin used in this instance, there is no particular limitation, but examples include epichlorohydrin, epibromohydrin, and β-methylepichlorohydrin. Of these, preferred is epichlorohydrin from the viewpoint of easy commercial availability.

Specific examples of the basic catalysts include alkaline earth metal hydroxides, alkali metal carbonates, and alkali metal hydroxides. Particularly, from the viewpoint of achieving excellent catalytic activity for an epoxy resin synthesis reaction, alkali metal hydroxides are preferred, and examples include sodium hydroxide and potassium hydroxide. When using the basic catalyst, the basic catalyst may be used in the form of an about 10 to 55% by mass aqueous solution, or may be used in a solid form. Further, when an organic solvent is used in the reaction, the reaction rate of the epoxidation step can be increased. With respect to the organic solvent, there is no particular limitation, but examples include ketones, such as acetone and methyl ethyl ketone; alcohols, such as methanol, ethanol, 1-propyl alcohol, isopropyl alcohol, 1-butanol, secondary butanol, and tertiary butanol; cellosolves, such as methylcellosolve and ethylcellosolve; ethers, such as tetrahydrofuran, 1,4-dioxane, 1,3-dioxane, and diethoxyethane; and aprotic polar solvents, such as acetonitrile, dimethyl sulfoxide, and dimethylformamide. These organic solvents may be individually used, or two or more types of the organic solvents may be appropriately used in combination for controlling the polarity.

Subsequently, the above-obtained reaction product is washed with water and then, the unreacted epihalohydrin and the organic solvent used are distilled off by distillation under a reduced pressure while heating. For obtaining an epoxide having a hydrolyzing halogen further reduced, the obtained reaction product can be dissolved in an organic solvent, such as toluene, methyl isobutyl ketone, or methyl ethyl ketone, and further subjected to reaction after adding an aqueous solution of an alkali metal hydroxide, such as sodium hydroxide or potassium hydroxide. In this instance, for the purpose of improving the reaction rate, the reaction may be performed in the presence of a phase transfer catalyst, such as a quaternary ammonium salt or a crown ether. When using a phase transfer catalyst, the amount of the phase transfer catalyst used is preferably in the range of from 0.1 to 3.0% by mass, based on the mass of the reaction product used. After completion of the reaction, the formed salt is removed by filtration, washing with water, and the like, and further a solvent, such as toluene or methyl isobutyl ketone, is distilled off under a reduced pressure while heating, obtaining an epoxide.

### <Step 2>

In the method of the invention, the step 2 is a recrystallization step for the epoxide obtained in the step 1, and, for example, there can be mentioned a method in which a solvent, such as toluene, methyl isobutyl ketone, or methyl ethyl ketone, is added to the epoxide obtained in the step 1 to dissolve the epoxide, and the resultant solution is stirred to deposit a crystalline epoxy resin. By subjecting the epoxide to the recrystallization step, the amount of halide ions generated in the step 1 and the compound corresponding to the peak P contained in the epoxide can be reduced. The deposited crystalline epoxy resin can be used in a solid state after being collected by filtration and dried, or can be used in an amorphous state after being dried and then further melted. Alternatively, the deposited crystalline epoxy resin can be used in the form of a resin solution after being collected by filtration and then adding another solvent thereto.

### <Curable Resin Composition>

The curable resin composition of the invention comprises the epoxy resin of the invention and a curing agent.

Examples of usable curing agents include various types of curing agents known as a curing agent for an epoxy resin, such as amine compounds, amide compounds, acid anhydride compounds, and phenol compounds.

Specific examples of the amine compound include diaminodiphenylmethane, diethylenetriamine, triethylenetetramine, diaminodiphenylsulfone, isophoronediamine, imidazole, a BF₃-amine complex, and a guanidine derivative. Examples of the amide compound include dicyandiamide and a polyamide resin synthesized from linolenic acid dimer and ethylenediamine. Examples of the acid anhydride compound include phthalic anhydride, trimellitic anhydride, pyromellitic anhydride, maleic anhydride, tetrahydrophthalic anhydride, methyltetrahydrophthalic anhydride, methylnadic anhydride, hexahydrophthalic anhydride, and methylhexahydrophthalic anhydride. Examples of the phenolic compound include a phenol novolac resin, a cresol novolac resin, an aromatic hydrocarbon formaldehyde resin-modified phenol resin, a dicyclopentadiene phenol addition type resin, a phenol aralkyl resin (Xylok resin), a naphthol aralkyl resin, a triphenylolmethane resin, a tetraphenylolethane resin, a naphthol novolac resin, a naphthol-phenol co-condensed novolac resin, a naphthol-cresol co-condensed novolac resin, and polyhydric phenolic hydroxyl group-containing compounds, such as a biphenyl-modified phenol resin (a polyhydric phenolic hydroxy group-containing compound in which phenol nuclei are linked via a bismethylene group), a biphenyl-modified naphthol resin (a polyhydric naphthol compound in which phenol nuclei are linked via a bismethylene group), an aminotriazine-modified phenol resin (a polyhydric phenolic hydroxy group-containing compound in which phenol nuclei are linked via melamine, benzoguanamine, etc.), and an alkoxy group-containing aromatic ring-modified novolac resin (a polyhydric phenolic hydroxy group-containing compound in which a phenol nucleus and an alkoxy group-containing aromatic ring are linked via formaldehyde).

In the curable resin composition, another thermosetting resin may be used together in addition to the epoxy resin described in detail above, as long as the effects of the present invention are not impaired.

Examples of the other thermosetting resin include a cyanate ester resin, a resin having a benzoxazine structure, a maleimide compound, an active ester resin, a vinylbenzyl compound, an acryl compound, and a copolymer of styrene and maleic anhydride. When the other thermosetting resin as above is used together, the use amount is not limited as long as the effects of the present invention are not impaired, but preferably the amount is in the range of 1 to 50 parts by mass in 100 parts by mass of the thermosetting resin composition.

Examples of the cyanate ester resin include a bisphenol A type cyanate ester resin, a bisphenol F type cyanate ester resin, a bisphenol E type cyanate ester resin, a bisphenol S type cyanate ester resin, a bisphenol sulfide type cyanate ester resin, a phenylene ether type cyanate ester resin, a naphthylene ether type cyanate ester resin, a biphenyl type cyanate ester resin, a tetramethylbiphenyl type cyanate ester resin, a polyhyroxynaphthalene type cyanate ester resin, a phenol novolac type cyanate ester resin, a cresol novolac type cyanate ester resin, a triphenylmethane type cyanate ester resin, a tetraphenylethane type cyanate ester resin, a dicyclopentadiene-phenol addition reaction type cyanate ester resin, a phenol aralkyl type cyanate ester resin, a naphthol novolac type cyanate ester resin, a naphthol aralkyl type cyanate ester resin, a naphthol-phenol co-condensed novolac type cyanate ester resin, a naphthol-cresol co-condensed novolac type cyanate ester resin, an aromatic hydrocarbon formaldehyde resin-modified phenol resin type cyanate ester resin, a biphenyl-modified novolac type cyanate ester resin, and an anthracene type cyanate ester resin. The compounds each may be used alone or two or more thereof may be used in combination.

Among the cyanate ester resins, in point that a cured product that is excellent particularly in the heat resistance can be obtained, a bisphenol A type cyanate ester resin, a bisphenol F type cyanate ester resin, a bisphenol E type cyanate ester resin, a polyhydroxynaphthalene type cyanate ester resin, a naphthylene ether type cyanate ester resin, and a novolac type cyanate ester resin are preferably used, and in point that a cured product that is excellent in dielectric characteristic can be obtained, a dicyclopentadiene-phenol addition reaction type cyanate ester resin is preferred.

The resin having a benzoxazine structure is not particularly limited, but examples thereof include a reaction product of bisphenol F, formalin, and aniline (an F-a type benzoxazine resin), a reaction product of diaminodiphenylmethane, formalin, and phenol (a P-d type benzoxazine resin), a reaction product of bisphenol A, formalin, and aniline, a reaction product of dihydroxydiphenyl ether, formalin, and aniline, a reaction product of diaminodiphenyl ether, formalin, and phenol, a reaction product of a dicyclopentadiene-phenol addition type resin, formalin, and aniline, a reaction product of phenolphthalein, formalin, and aniline, and a reaction product of diphenylsulfide, formalin, and aniline. The compounds each may be used alone or two or more thereof may be used in combination.

Examples of the maleimide compound include compounds represented by the following structural formulae (i) to (iii).

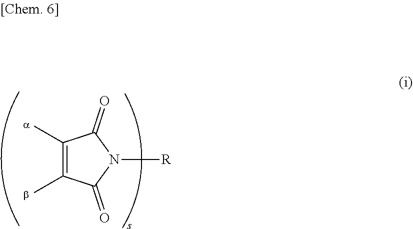

In the formula, R is an s-valent organic group, α and β each represent any of a hydrogen atom, a halogen atom, an alkyl group, and an aryl group, and s is an integer of 1 or more.

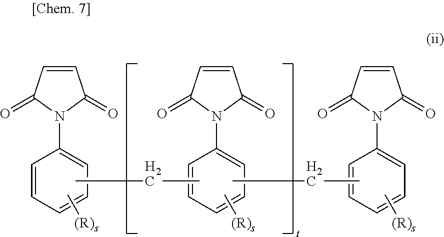

In the formula, R is any of a hydrogen atom, an alkyl group, an aryl group, an aralkyl group, a halogen atom, a hydroxy group, and an alkoxy group, s is an integer of 1 to 3, and t is the average number of the repeating units and represents 0 to 10.

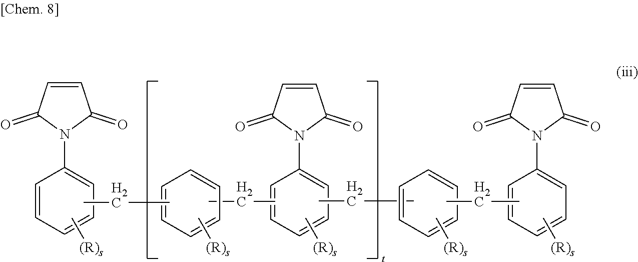

In the formula, R is any of a hydrogen atom, an alkyl group, an aryl group, an aralkyl group, a halogen atom, a hydroxy group, and an alkoxy group, s is an integer of 1 to 3, and t is the average number of the repeating units and represents 0 to 10.

The compounds each may be used alone or two or more thereof may be used in combination.

The active ester resin is not particularly limited, but generally, compounds having, in a molecule, two or more ester groups having high reaction activity such as a phenol ester, a thiophenol ester, an N-hydroxyamine ester, and an ester of a heterocyclic hydroxy compound are preferably used. The active ester resin is preferably one obtained by a condensation reaction of a carboxylic acid compound and/or a thiocarboxylic acid compound and a hydroxy compound and/or a thiol compound. In particular, from the viewpoint of enhancing heat resistance, an active ester resin obtained from a carboxylic acid compound or a halide thereof and a hydroxy compound is preferred, and an active ester resin obtained from a carboxylic acid compound or a halide thereof and a phenol compound and/or a naphthol compound is more preferred. Examples of the carboxylic acid compound include benzoic acid, acetic acid, succinic acid, maleic acid, itaconic acid, phthalic acid, isophthalic acid, terephthalic acid, and pyromellitic acid, or a halide thereof. Examples of the phenol compound or a naphthol compound include hydroquinone, resorcin, bisphenol A, bisphenol F, bisphenol S, dihydroxydiphenyl ether, phenolphthalein, methylated bisphenol A, methylated bisphenol F, methylated bisphenol S, phenol, o-cresol, m-cresol, p-cresol, catechol, α-naphthol, β-naphthol, 1,5-dihydroxynaphthalene, 1,6-dihydroxynaphthalene, 2,6-dihydroxynaphthalene, dihydroxybenzophenone, trihydroxybenzophenone, tetrahydroxybenzophenone, phloroglucin, benzenetriol, and dicyclopentadiene-phenol addition type resin.

As the active ester resin, specifically, an active ester type resin containing a dicyclopentadiene-phenol addition structure, an active ester resin containing a naphthalene structure, an active ester resin which is an acetylated compound of phenol novolac, an active ester resin which is a benzoylated product of phenol novolac, and the like are preferred, and among them, an active ester resin containing a dicyclopentadiene-phenol addition structure and an active ester resin containing a naphthalene structure are more preferred in point of excellent enhancement of pealing strength. Specific examples of the active ester resin containing a dicyclopentadiene-phenol addition structure include a compound represented by the following general formula (iv).

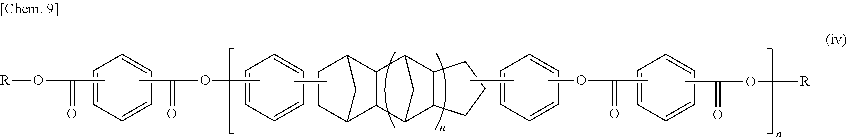

In the formula (iv), R is a phenyl group or a naphthyl group, u represents 0 or 1, n is the average number of the repeating units and represents 0.05 to 2.5. Incidentally, from the view point of lowering dielectric loss tangent and increasing heat resistance of a cured product of the resin composition, R is preferably a naphthyl group, u is preferably 0, and n is preferably 0.25 to 1.5.

In the curable resin composition of the present invention, although the curing proceeds by the curable resin composition alone, a curing accelerator may be used together. Examples of the curing accelerator include a tertiary amine compound such as imidazole and dimethylaminopyridine; a phosphorus-based compound such as triphenylphosphine; boron trifluoride and a boron trifluoride amine complex such as boron trifluoride monoethylamine complex; an organic acid compound such as thiodipropionic acid; a benzoxazine compound such as thiodiphenol benzoxazine, and sulfonyl benzoxazine; and a sulfonyl compound. The compounds each may be used alone or two or more thereof may be used in combination. The amount of the catalyst added is preferably in the range of 0.001 to 15 parts by mass in 100 parts by mass of the curable resin composition.

When the curable resin composition of the present invention is used in an application requiring high flame retardancy, a halogen-free type flame retardant containing substantially no halogen atom may be incorporated.

Examples of the halogen-free type flame retardant include a phosphorus-based flame retardant, a nitrogen-based flame retardant, a silicone-based flame retardant, an inorganic flame retardant, and an organic metal salt-based flame retardant. The use thereof is by no means limited, and the flame retardants each may be used alone, plural flame retardants of the same type may be used, or flame retardants of different types may be used in combination.

The phosphorus-based flame retardant used may be an inorganic or organic compound. Examples of the inorganic compound include red phosphorus, ammonium phosphate compounds such as monoammonium phosphate, diammonium phosphate, triammonium phosphate, and ammonium polyphosphate, and an inorganic nitrogen-containing phosphorus compound such as phosphoric amide.

The red phosphorus is preferably previously subjected to a surface treatment for the purpose of preventing hydrolysis and the like, and examples of the method for surface treatment include (i) a method of coating with an inorganic compound such as magnesium hydroxide, aluminum hydroxide, zinc hydroxide, titanium hydroxide, bismuth oxide, bismuth hydroxide, and bismuth nitrate, or a mixture thereof, (ii) a method of coating with a mixture of an inorganic compound such as magnesium hydroxide, aluminum hydroxide, zinc hydroxide, and titanium hydroxide, and a thermosetting resin such as a phenol resin, and (iii) a method of double coating with a thermosetting resin such as a phenol resin over an inorganic compound such as magnesium hydroxide, aluminum hydroxide, zinc hydroxide, or titanium hydroxide.

Examples of the organic phosphorus-based compound include a general-purpose organic phosphorus-based compound, such as a phosphoric acid ester compound, a phosphonic acid compound, a phosphinic acid compound, a phosphine oxide compound, a phosphorane compound, and an organic nitrogen-containing phosphorus compound, as well as a cyclic organic phosphorus compound, such as 9,10-dihydro-9-oxa-10-phosphaphenanthrene-10-oxide, 10-(2,5-dihydroxyphenyl)-10H-9-oxa-10-phosphaphenanthrene-10-oxide, and 10-(2,7-dihydroxynaphthyl)-10H-9-oxa-10-phosphaphenanthrene-10-oxide, and a derivative obtained by reacting the above compound with a compound such as an epoxy resin and a phenol resin.

The amount of the phosphorus-based flame retardant incorporated is appropriately selected depending on the kind of the phosphorus-based flame retardant, other components in the curable resin composition, and the desired degree of the flame retardancy. For example, in 100 parts by mass of the curable resin composition in which all of the halogen-free type flame retardant and other fillers, additives, and the like are blended, in the case of using red phosphorus as the halogen-free type flame retardant, red phosphorus is preferably incorporated in the range of 0.1 parts by mass to 2.0 parts by mass, and in the case of using an organic phosphoric compound, the organic phosphoric compound is preferably incorporated in the range of 0.1 parts by mass to 10.0 parts by mass, and more preferably in the range of 0.5 parts by mass to 6.0 parts by mass.

In the case of using the phosphorus-based flame retardant, hydrotalcite, magnesium hydroxide, a boron compound, zirconium oxide, a black dye, calcium carbonate, zeolite, zinc molybdate, activated carbon, etc. may be used together with the phosphorus-based flame retardant.

Examples of the nitrogen-based flame retardant include a triazine compound, a cyanuric acid compound, an isocyanuric acid compound, and a phenothiazine, and a triazine compound, a cyanuric acid compound, and an isocyanuric acid compound are preferred.

Examples of the triazine compound include melamine, acetoguanamine, benzoguanamine, melon, melam, succinoguanamine, ethylenedimelamine, melamine polyphosphate, and triguanamine, as well as, for example, (1) an aminotriazine sulfate compound such as guanyl melamine sulfate, melem sulfate, and melam sulfate, (2) a co-condensed compound of a phenol compound such as phenol, cresol, xylenol, butylphenol, and nonylphenol, a melamine compound such as melamine, benzoguanamine, acetoguanamine, and formguanamine, and formaldehyde, (3) a mixture of the co-condensed compound of the above (2) and a phenol resin, such as a phenol-formaldehyde condensed compound, and (4) a compound obtained by further modifying the above (2) or (3) with tung oil or an isomerized linseed oil.

Examples of the cyanuric acid compound include cyanuric acid and melamine cyanurate.

The amount of the nitrogen-based flame retardant incorporated is appropriately selected depending on the kind of the nitrogen-based flame retardant, other components of the curable resin composition, and the desired degree of the flame retardancy. For example, in 100 parts by mass of the curable resin composition in which all of the halogen-free type flame retardant and other fillers, additives, and the like are blended, the nitrogen-based flame retardant is preferably incorporated in the range of 0.05 to 10 parts by mass, and more preferably incorporated in the range of 0.1 parts by mass to 5 parts by mass.

In the case of using the nitrogen-based flame retardant, a metal hydroxide, a molybdenum compound, or the like may be used together.

The silicone-based flame retardant can be used without any particular limitation as long as it is an organic compound containing a silicon atom, and examples thereof include a silicone oil, a silicone rubber, and a silicone resin. The amount of the silicone-based flame retardant incorporated is appropriately selected depending on the kind of the silicone-based flame retardant, other components of the curable resin composition, and the desired degree of the flame retardancy. For example, in 100 parts by mass of the curable resin composition in which all of the halogen-free type flame retardant and other fillers, additives, and the like are blended, the silicone-based flame retardant is preferably incorporated in the range of 0.05 to 20 parts by mass. In the case of using the silicone-based flame retardant, a molybdenum compound, an alumina, or the like may be used together.

Examples of the inorganic flame retardant include a metal hydroxide, a metal oxide, a metal carbonate compound, a metal powder, a boron compound, and a low-melting glass.

Examples of the metal hydroxide include aluminum hydroxide, magnesium hydroxide, dolomite, hydrotalcite, calcium hydroxide, barium hydroxide, and zirconium hydroxide.

Examples of the metal oxide include zinc molybdate, molybdenum trioxide, zinc stannate, tin oxide, aluminum oxide, iron oxide, titanium oxide, manganese oxide, zirconium oxide, zinc oxide, molybdenum oxide, cobalt oxide, bismuth oxide, chromium oxide, nickel oxide, copper oxide, and tungsten oxide.

Examples of the metal carbonate compound include zinc carbonate, magnesium carbonate, calcium carbonate, barium carbonate, basic magnesium carbonate, aluminum carbonate, iron carbonate, cobalt carbonate, and titanium carbonate.

Examples of the metal powder include aluminum, iron, titanium, manganese, zinc, molybdenum, cobalt, bismuth, chromium, nickel, copper, tungsten, and tin.

Examples of the boron compound include zinc borate, zinc metaborate, barium metaborate, boric acid, and borax.

Examples of the low-melting glass include Ceepree (Bokusui Brown), hydrated glass SiO₂—MgO—H₂O, and a PbO—B₂O₃-based, ZnO—P₂O₅—MgO-based, P₂O₅—B₂O₃—PbO—MgO-based, P—Sn—O—F-based, PbO—V₂O₅—TeO₂-based, Al₂O₃—H₂O-based, and lead borosilicate-based glass compound.

The amount of the inorganic flame retardant incorporated is appropriately selected depending on the kind of the inorganic flame retardant, other components of the curable resin composition, and the desired degree of the flame retardancy. For example, in 100 parts by mass of the curable resin composition in which all of the halogen-free type flame retardant and other fillers, additives, and the like are blended, the inorganic flame retardant is preferably incorporated in the range of 0.05 parts by mass to 20 parts by mass, and more preferably incorporated in the range of 0.5 parts by mass to 15 parts by mass.

Examples of the organic metal salt-based flame retardant include ferrocene, an acetylacetonate metal complex, an organic metal carbonyl compound, an organic cobalt salt compound, an organic sulfonic acid metal salt, and a compound in which a metal atom and an aromatic compound or a heterocyclic compound are connected via an ionic bond or a coordinate bond.

The amount of the organic metal salt-based flame retardant incorporated is appropriately selected depending on the kind of the organic metal salt-based flame retardant, other components of the curable resin composition, and the desired degree of the flame retardancy. For example, with respect to 100 parts by mass of the curable resin composition, for example, the curable resin composition, in which all of the halogen-free type flame retardant and other fillers, additives, and the like are blended, the organic metal salt-based flame retardant is preferably incorporated in the range of 0.005 parts by mass to 10 parts by mass.

In the curable resin composition of the present invention, an inorganic filler may be incorporated as required. Examples of the inorganic filler include a fused silica, a crystal silica, an alumina, silicon nitride, and aluminum hydroxide. When the inorganic filler is incorporated in an especially large amount, a fused silica is preferably used. The fused silica may be used in any shape of flake and sphere, but for increasing the amount of the fused silica incorporated and suppressing increase of the melt viscosity of the molding material, it is preferred that the fused silica in a sphere shape is mainly used. For further increasing the amount of the spherical silica incorporated, it is preferred that the particle size distribution of the spherical silica is appropriately adjusted. The filling rate thereof is preferably higher in view of the flame retardancy, and the filling rate is particularly preferably 20% by mass or more based on the total mass of the curable resin composition. In addition, when the curable resin composition is used for such an application as a conductive paste, a conductive filler such as silver powder and copper powder can be used.

In the curable resin composition of the present invention, in addition to the above, various compounding agents such as a silane coupling agent, a mold release agent, a pigment, and an emulsifier can be added, as required.

The curable resin composition of the invention can be obtained by uniformly mixing the above-mentioned components, and, by heating the curable resin composition, it is cured, so that a cured product can be easily obtained. Specifically, the curable resin composition can be obtained by uniformly mixing the above-mentioned components, and, by heating the curable resin composition preferably at a temperature of 20 to 250° C., a cured product can be easily obtained. As examples of the thus obtained cured products, there can be mentioned molded cured products, such as a stacked material, a cast material, an adhesive layer, a coating film, and a film.

### <Use of the Curable Resin Composition>

Uses of the curable resin composition of the invention include insulating materials for circuit board, such as a hard printed wiring board material, a resin composition for flexible wiring board, and an interlayer dielectric material for buildup substrate, a semiconductor encapsulating material, a conductive paste, an adhesive film for buildup, a resin casting material, and an adhesive. Among these various uses, in the use as a hard printed wiring board material, an insulating material for electronic circuit board, and an adhesive film for buildup, the curable resin composition can be used as an insulating material for a so-called electronic part built-in substrate having a passive part, such as a capacitor, or an active part, such as an IC chip, embedded in the substrate. Of these, for fully utilizing advantageous properties not only in that the resin composition has high fluidity, but also in that a cured product obtained therefrom has excellent heat resistance and high-temperature stability, the curable resin composition is preferably used in a semiconductor encapsulating material, a semiconductor device, a prepreg, a circuit board, a buildup substrate, a buildup film, a fiber-reinforced composite material, and a fiber-reinforced resin molded article.

### 1. Semiconductor Encapsulating Material

The semiconductor encapsulating material of the invention contains at least the curable resin composition and an inorganic filler. As a method for obtaining the semiconductor encapsulating material from the curable resin composition, there can be mentioned a method in which the curable resin composition and a component to be incorporated, such as an inorganic filler, (and, if necessary, the above-mentioned curing accelerator) are melt-mixed satisfactorily with each other until the resultant mixture becomes uniform. For making the mixture uniform, if necessary, an extruder, a kneader, a roll, or the like may be used. In this case, as the inorganic filler, fused silica is generally used, but, when the semiconductor encapsulating material is used as a highly thermally conductive semiconductor encapsulating material for a power transistor or power IC, crystalline silica having a thermal conductivity higher than fused silica, alumina, silicon nitride, or the like may be highly packed, or fused silica, crystalline silica, alumina, or silicon nitride, or the like may be used. With respect to the filling ratio, relative to 100 parts by mass of the curable resin composition, the inorganic filler is preferably used in an amount in the range of from 30 to 95% by mass, and, especially for improving the flame retardancy, moisture resistance, and resistance to cracking due to soldering and for reducing the linear expansion coefficient, the amount is more preferably 70 parts by mass or more, further preferably 80 parts by mass or more.

### 2. Semiconductor Device

The semiconductor device of the invention is obtained by curing the above-mentioned semiconductor encapsulating material. As a method for obtaining the semiconductor device from the semiconductor encapsulating material, there can be mentioned a method in which the semiconductor encapsulating material is cast, or molded using a transfer molding machine, an injection molding machine, or the like, and further heated at 50 to 200° C. for 2 to 10 hours.

### 3. Prepreg

The prepreg of the invention is a semi-cured product of an impregnated substrate comprising the curable resin composition and a reinforcing substrate, and is obtained by impregnating a reinforcing substrate with a dilution prepared by diluting the above-mentioned curable resin composition with an organic solvent, and semi-curing the resultant impregnated substrate. As a method for obtaining the prepreg from the curable resin composition, there can be mentioned a method in which a reinforcing substrate (such as paper, a glass cloth, glass nonwoven fabric, aramid paper, an aramid cloth, a glass mat, or a glass roving cloth) is impregnated with the curable resin composition in the form of a varnish having an organic solvent incorporated, and then heated at a heating temperature according to the type of the solvent used, preferably at 50 to 170° C. to obtain a prepreg. With respect to the mass percentage of the resin composition and reinforcing substrate used in this instance, there is no particular limitation, but, generally, they are preferably prepared so that the resin content of the prepreg becomes 20 to 60% by mass.

Examples of the organic solvent used here include methyl ethyl ketone, acetone, dimethylformamide, methyl isobutyl ketone, methoxy propanol, cyclohexanone, methyl cellosolve, ethyldiglycol acetate, and propyleneglycol monomethyl ether acetate, and the selection and the suitable use amount may be appropriately selected depending on the application. For example, in the case where a printed circuit board is further produced from the prepreg as described below, a polar solvent having a boiling point of 160° C. or lower such as methyl ethyl ketone, acetone, and dimethylformamide is preferably used, and such a solvent is preferably used in a proportion of 40% by mass to 80% by mass in terms of the non-volatile matter.

### 4. Circuit Board

The circuit board of the invention has the curable resin composition in the form of a plate and a copper foil, and is obtained by stacking a copper foil on a substrate, which is obtained in the form of a plate from a varnish obtained by diluting the above-mentioned curable resin composition with an organic solvent, and subjecting the stacked materials to heat-pressure molding. Specifically, for example, as a method for producing a hard printed wiring board, there can be mentioned a method in which an organic solvent is further incorporated into the curable resin composition in a varnish form containing the organic solvent to obtain a varnish, and a reinforcing substrate is impregnated with the resultant varnish and semi-cured to obtain the prepreg of the invention, and a copper foil is stacked on the prepreg, followed by thermo-compression bonding. Examples of usable reinforcing substrates include paper, a glass cloth, glass nonwoven fabric, aramid paper, an aramid cloth, a glass mat, and a glass roving cloth. The above-mentioned method is described in more detail. First, the above-mentioned curable resin composition in a varnish form is heated at a heating temperature according to the type of the solvent used, preferably at 50 to 170° C. to obtain a prepreg which is a cured product. With respect to the mass percentage of the curable resin composition and reinforcing substrate used in this instance, there is no particular limitation, but, generally, they are preferably prepared so that the resin content of the prepreg becomes 20 to 60% by mass. Then, the thus obtained prepreg is stacked by a general method, and a copper foil is appropriately stacked thereon and subjected to thermo-compression bonding under a pressure of 1 to 10 MPa at 170 to 250° C. for 10 minutes to 3 hours, obtaining an intended circuit board. When producing a flexible wiring board from the curable resin composition of the invention, the epoxy resin and an organic solvent are mixed and applied to an electrically insulating film using a coating apparatus, such as a reverse-roll coater or a comma coater. Then, the resultant film is heated using a heating apparatus at 60 to 170° C. for 1 to 15 minutes to volatilize the solvent, forming an adhesive composition of a B-stage. Then, a metal foil is thermo-compression bonded onto the adhesive using a heating roll or the like. In this instance, the compression bonding pressure is preferably 2 to 200 N/cm² and the compression bonding temperature is preferably 40 to 200° C. When satisfactory adhesion performance is obtained, the procedure may be ended. When complete curing is needed, the resultant material is preferably further subjected to post-curing under conditions at 100 to 200° C. for 1 to 24 hours. The thickness of the finally cured adhesive composition film is preferably in the range of from 5 to 100 μm.

### 5. Buildup Substrate

The buildup substrate of the invention is obtained by applying, to a circuit board having a circuit formed, an adhesive film for buildup having a dried coating film of the curable resin composition and a substrate film, heat-curing the film, forming unevenness in the resultant circuit board, and then subjecting the circuit board to plating treatment. As a method for obtaining the buildup substrate from the curable resin composition, there can be mentioned a method having the following steps 1 to 3. In the step 1, the curable resin composition having appropriately incorporated thereinto a rubber, a filler, or the like is first applied to a circuit board having formed a circuit by a spray coating method, a curtain coating method, or the like, and then cured. In the step 2, if necessary, a predetermined through-hole portion or the like is formed in the circuit board having the curable resin composition applied, and then the resultant circuit board is treated with a roughening agent and the surface of the board is washed with warm water to form unevenness in the board, followed by plating treatment with a metal, such as copper. In the step 3, the operations of the steps 1 and 2 are repeated successively as desired, and a resin insulating layer and a conductive layer having a predetermined circuit pattern are alternately built up to form a buildup substrate. In the above steps, the formation of a through-hole portion is advantageously conducted after forming the resin insulating layer as the outermost layer. Further, with respect to the buildup substrate of the invention, when a copper foil having a resin, which is obtained by semi-curing the resin composition on a copper foil, is thermo-compression bonded onto a wiring board having formed a circuit at 170 to 300° C., the buildup substrate can be produced without the step for forming a roughened surface and performing a plating treatment.

### 6. Buildup Film

As a method for obtaining a buildup film from the curable resin composition of the present invention, for example, a method in which a curable resin composition is applied on a support film, and then the film is dried to form a resin composition layer on the support film may be exemplified. In the case where the curable resin composition of the present invention is used for a buildup film, it is important that the film is softened at a temperature condition of lamination in a vacuum lamination method (generally from 70° C. to 140° C.) to achieve a flowability (resin flow) that allows for the resin to fill in via holes or through holes which are present in the circuit board simultaneously with the lamination of the circuit board. The components are preferably blended so as to exhibit such characteristic.

Here, the through holes in the circuit board generally have a diameter of 0.1 to 0.5 mm and generally have a depth of 0.1 to 1.2 mm, and in general the resin is preferably allowed to fill in the holes in the above range. Incidentally, when both the surfaces of the circuit board are laminated, it is desired that about one-half of the through hole is filled.

As a specific method for producing the buildup film described above, a method in which, after an organic solvent is blended into the curable resin composition to prepare a varnish, the composition is applied on a surface of a support film (Y), and further, the organic solvent is dried by heating, blowing with hot air or other method, to form a curable resin composition layer (X), may be exemplified.

As the organic solvent used here, for example, ketones such as acetone, methyl ethyl ketone, and cyclohexanone, acetic acid esters such as ethyl acetate, butyl acetate, cellosolve acetate, propyleneglycol monomethyl ether acetate, and carbitol acetate, cellosolve, carbitols such as butylcarbitol, aromatic hydrocarbons such as toluene and xylene, dimethylformamide, dimethylacetamide, N-methylpyrrolidone, etc. are preferably used, and the solvent is preferably used in a proportion of 30% by mass to 60% by mass in terms of the non-volatile matter.

Incidentally, the thickness of the resin composition layer (X) formed is generally required to be the thickness of the conductor layer or more. The thickness of the conductor layer included in the circuit board is generally in the range of 5 to 70 μm, and therefore the thickness of the resin composition layer is preferably 10 to 100 μm. Incidentally, the resin composition layer (X) in the present invention may be protected by a protection film described later. By protecting with a protection film, it is possible to prevent deposition of dust and scratches on the surface of the resin composition layer.

Examples of the support film and protection film include polyolefins such as polyethylene, polypropylene, and polyvinyl chloride, polyesters such as polyethylene terephthalate (hereinunder, sometimes abbreviated as “PET”) and polyethylene naphthalate, polycarbonate, and polyimide, and further include a release paper and a metal foil such as copper foil and aluminum foil. Incidentally, the support film and protection film may be previously subjected to a mud treatment, a corona treatment, as well as a mold release treatment. The thickness of the support film is not particularly limited, but generally 10 to 150 μm, and preferably in the range of 25 to 50 μm. The thickness of the protection film is preferably 1 to 40 μm.

The support film (Y) is released after the support film is laminated on the circuit board, or after the insulating layer is formed by thermal curing. By releasing the support film (Y) after the curable resin composition layer which constitutes the buildup film is thermally cured, deposition of dust and the like in the curing step can be prevented. In the case of releasing after curing, in general, the support film is subjected to a mold release treatment in advance.

Incidentally, a multilayer printed circuit board can be produced from the buildup film obtained as above. For example, after releasing the protection film in the case where the resin composition layer (X) is protected by the protection film, the resin composition layer (X) is laminated on one or both surfaces of the circuit board in direct contact with the circuit board, for example, by a vacuum lamination method. The lamination method may be a batch process, or may be a continuous process by a roll. If necessary, the buildup film and the circuit board may be heated (preheated) before the lamination. As the condition of the lamination, the pressing temperature (lamination temperature) is preferably 70 to 140° C., the pressing pressure is preferably 1 to 11 kgf/cm² (9.8×10⁴ to 107.9×10⁴ N/m²), and the lamination is preferably performed under a reduced air pressure of 20 mmHg (26.7 hPa) or lower.

### 7. Fiber-Reinforced Composite Material

The fiber-reinforced composite material of the invention is a reinforcing fiber impregnated with the curable resin composition, that is, the fiber-reinforced composite material contains at least the curable resin composition and a reinforcing fiber. As a method for obtaining the fiber-reinforced composite material from the curable resin composition, there can be mentioned a method in which the components constituting the curable resin composition are uniformly mixed to prepare a varnish, and then a reinforcing substrate formed from a reinforcing fiber is impregnated with the varnish, and then subjected to polymerization reaction, producing the fiber-reinforced composite material.

The specific curing temperature in the polymerization reaction is preferably in the temperature range of 50 to 250° C., and it is particularly preferred that curing at 50 to 100° C. is performed to produce a tack-free cured product, and is then further treated under a temperature condition of 120 to 200° C.

Here, the reinforcing fiber may be any of a twisted yarn, an untwisting yarn, a twistless yarn, and the like, but an untwisting yarn and a twistless yarn are preferred in point of providing a fiber-reinforced plastic member having both of moldability and mechanical strength. Moreover, the reinforcing fiber used may have a form in which fibers are aligned in one direction or a form of textile. In a textile, plain weave, satin weave, or the like may be selected appropriately depending on the part where the material is used and the use purpose. Specifically, because of excellent mechanical strength and durability, a carbon fiber, a glass fiber, an aramid fiber, a boron fiber, an alumina fiber, a silicon carbide fiber, etc. are exemplified, and two or more thereof may be used in combination. Among them, since strength of a molded article is excellent, a carbon fiber is preferred, and as such a carbon fiber, various types such as a polyacrylonitrile-based, a pitch-based, and a rayon-based carbon fibers may be used. Among these, a polyacrylonitrile-based one by which a carbon fiber having high strength can be easily obtained is preferred. Here, the amount of the reinforcing fiber used when the reinforcing substrate formed of the reinforcing fiber is impregnated with the varnish to prepare the fiber-reinforced composite material is preferably such an amount that the volume content of the reinforcing fiber in the fiber-reinforced composite material is in the range of 40% to 85%.

### 8. Fiber-Reinforced Resin Molded Article

The fiber-reinforced molded article of the invention is obtained by curing the above-mentioned fiber-reinforced composite material. As a method for obtaining the fiber-reinforced molded article from the curable resin composition of the invention, there can be mentioned a method in which a prepreg having a reinforcing fiber impregnated with the varnish is produced by: a hand lay-up method or a spray-up method in which fiber aggregate is placed on the bottom of a mold and the varnish is stacked in multiple layers on the fiber; a vacuum bag method in which, using any of a male mold and a female mold, the varnish is stacked on a substrate formed from a reinforcing fiber while impregnating the substrate with the varnish, and the resultant substrate is molded, and a flexible mold capable of exerting a pressure to the molded article is placed on the molded article and airtightly sealed, followed by vacuum (reduced pressure) molding; an SMC pressing method in which the varnish containing a reinforcing fiber is preliminarily shaped into a sheet form and subjected to compression molding using a mold; an RTM method in which the varnish is injected into a matched mold in which a fiber is placed on the whole of bottom; or and like, and the produced prepreg is hardened by firing using a large-size autoclave. The above-obtained fiber-reinforced resin molded article is a molded article having a reinforcing fiber and a cured product of the curable resin composition, and, specifically, the amount of the reinforcing fiber in the fiber-reinforced molded article is preferably in the range of from 40 to 70% by mass, especially preferably in the range of from 50 to 70% by mass from the viewpoint of the strength.

### EXAMPLES

The present invention is specifically described below with reference to examples and comparative examples. As used hereinafter, “parts” and “%” are based on the mass unless otherwise specified. Incidentally, GPC measurement was performed under the following conditions.

### <GPC Measurement Conditions>

Measuring instrument: “HLC-8320 GPC” manufactured by Tosoh Corporation,

Column: guard column “HXL-L” manufactured by Tosoh Corporation

+ “TSK-GEL G2000HXL” manufactured by Tosoh Corporation

+ “TSK-GEL G2000HXL” manufactured by Tosoh Corporation

+ “TSK-GEL G3000HXL” manufactured by Tosoh Corporation

+ “TSK-GEL G4000HXL” manufactured by Tosoh Corporation

Detector: RI (refractive index detector)

Data processing: “GPC workstation EcoSEC-WorkStation” manufactured by Tosoh Corporation

### Measurement Conditions:

Column temperature: 40° C.

Eluent: tetrahydrofuran

Flow rate: 1.0 ml/min

Standard: the following monodispersed polystyrenes with known molecular weights were used according to the measurement manual for the “GPC workstation EcoSEC-WorkStation.”

(Polystyrene Used)

“A-500” manufactured by Tosoh Corporation

“A-1000” manufactured by Tosoh Corporation

“A-2500” manufactured by Tosoh Corporation

“A-5000” manufactured by Tosoh Corporation

“F-1” manufactured by Tosoh Corporation

“F-2” manufactured by Tosoh Corporation

“F-4” manufactured by Tosoh Corporation

“F-10” manufactured by Tosoh Corporation

“F-20” manufactured by Tosoh Corporation

“F-40” manufactured by Tosoh Corporation

“F-80” manufactured by Tosoh Corporation

“F-128” manufactured by Tosoh Corporation

Sample: obtained by filtering a 1.0 mass % solution in tetrahydrofuran in terms of the resin solid through a microfilter (50 μl).

### Example 1

### <Production of Epoxide (I)>

To a flask equipped with a thermometer, a dropping funnel, a condenser, and a stirrer were added 320 g (2 mol) of 2,7-dihydroxynaphthalene and 320 g of isopropyl alcohol, and they were satisfactorily mixed with each other. Then, 33 g of 49% NaOH was added to the resultant mixture, followed by temperature elevation to 70° C. Subsequently, 81 g of 37% formalin was added dropwise to the mixture over one hour while maintaining the liquid temperature at 70° C. Then, stirring was continued at 70° C. for 2 hours to complete a dimerization reaction. 1,850 g (20 mol) of epichlorohydrin was added to the reaction mixture, and 360 g (4.4 mol) of 49% NaOH was added dropwise to the resultant mixture over 3 hours at 50° C. Then, stirring was continued at 50° C. for one hour to complete an epoxidation reaction, and stirring was stopped and the lower layer was discarded. Subsequently, excess epichlorohydrin was recovered by distillation, and then 1,000 g of methyl isobutyl ketone (hereinafter, referred to as “MIBK”) was added to dissolve the crude resin. 30 g of 10% NaOH was added to the solution, and the resultant mixture was stirred at 80° C. for 3 hours, and stirring was stopped and the lower layer was discarded. The resultant material was washed with water twice using 300 g of water, and subjected to dehydration, filtration, and desolvation to obtain 501 g of an epoxide (I). A GPC chart of the epoxide (I) is shown in FIG. 1. The results of the measurement of ¹³C-NMR and FD-MS have confirmed that the epoxide (I) is the epoxy resin represented by the structural formula (1) above. Further, from the GPC chart shown in FIG. 1, it was found that, in a GPC measurement, with respect to the epoxy resin represented by the structural formula (1) above, the ratio of the peak area (51) of a peak P appearing between peaks of n=0 and n=1 to the peak area (S2) of n=0, i.e., S1/S2 was 0.0783. Further, from the GPC chart shown in FIG. 1, it was found that the ratio of the area of the peak P to the whole peak area of the epoxy resin was 4.52% by area. With respect to the obtained epoxy resin, the epoxy equivalent was 161 g/eq, the ICI viscosity at 150° C. was 3.8 dPa·s, and the content of the epoxy resin represented by the structural formula (1) above wherein n=0 was 57.7% by area as measured by GPC.

### <Production of Crystalline Epoxy Resin (A-1)>

To a flask equipped with a thermometer, a dropping funnel, a condenser, and a stirrer were added 500 g of the epoxide (I) and 300 g of MIBK, and the epoxide was dissolved at 80° C., and then the resultant solution was cooled to room temperature while stirring, and stirring was continued for 10 hours. The deposited crystals were collected by filtration, and washed with 500 g of MIBK three times to obtain an intended crystalline epoxy resin (A-1). A GPC chart of the epoxy resin (A-1) is shown in FIG. 2. From the GPC chart, it was found that, in a GPC measurement, with respect to the epoxy resin represented by the structural formula (1) above, the ratio of the peak area (S1) of a peak P appearing between peaks of n=0 and n=1 to the peak area (S2) of n=0 of the epoxy resin, i.e., S1/S2 was 0.0626. Further, the ratio of the area of the peak P to the whole peak area of the epoxy resin was 4.39%. With respect to the obtained epoxy resin (A-1), the epoxy equivalent was 158 g/eq, the ICI viscosity at 150° C. was 3.3 dPa·s, and the content of the epoxy resin represented by the structural formula (1) above wherein n=0 was 70.1% by area.

### Example 2

### Production of Crystalline Epoxy Resin (A-2)

An intended crystalline epoxy resin (A-2) was obtained in substantially the same manner as in Example 1 except that the amount of the epoxy resin (I) was changed from 500 g to 300 g. In a GPC measurement of the obtained epoxy resin (A-2), the ratio of the peak area (S1) of a peak P appearing between peaks of n=0 and n=1 to the peak area (S2) of n=0 of the epoxy resin, i.e., S1/S2 was 0.0285. Further, the ratio of the area of the peak P to the whole peak area of the epoxy resin was 2.18%. With respect to the obtained epoxy resin (A-2), the epoxy equivalent was 153 g/eq, the ICI viscosity at 150° C. was 2.7 dPa·s, and the content of the epoxy resin represented by the structural formula (1) above wherein n=0 was 76.4% by area.

### Example 3

### Production of Crystalline Epoxy Resin (A-3)

An intended crystalline epoxy resin (A-3) was obtained in substantially the same manner as in Example 1 except that the amount of the epoxy resin (I) was changed from 500 g to 200 g. From the GPC chart of the obtained epoxy resin (A-3), it was found that, in a GPC measurement, with respect to the epoxy resin represented by the structural formula (1) above, the ratio of the peak area (S1) of a peak P appearing between peaks of n=0 and n=1 to the peak area (S2) of n=0 of the epoxy resin, i.e., S1/S2 was 0.0164. Further, the ratio of the area of the peak P to the whole peak area of the epoxy resin was 1.42%. With respect to the obtained epoxy resin (A-3), the epoxy equivalent was 147 g/eq, the ICI viscosity at 150° C. was 1.8 dPa·s, and the content of the epoxy resin represented by the structural formula (1) above wherein n=0 was 86.4% by area.

### Examples 4 to 6 and Comparative Examples 1 and 2

### Preparation of a Curable Resin Composition and a Stacked Plate

The compounds shown below were blended in the formulation shown in Table 1, and then melt-kneaded using two rolls at a temperature of 90° C. for 5 minutes to synthesize an intended curable resin composition. The abbreviations shown in Table 1 mean the following compounds.
Epoxy resin I: Epoxide synthesized in Example 1
Epoxy resin A-1: Epoxy resin obtained in Example 1
Epoxy resin A-2: Epoxy resin obtained in Example 2
Epoxy resin A-3: Epoxy resin obtained in Example 3
Epoxy resin A-4: Triphenolmethane epoxy resin; epoxy equivalent: 172 g/eq; EPPN-502H (manufactured by Nippon Kayaku Co., Ltd.)
Curing agent TD-2093Y: Phenolic novolak resin; hydroxyl equivalent: 104 g/eq (manufactured by DIC Corporation)
TPP: Triphenylphosphine
Fused silica: Spherical silica “FB-560”, manufactured by Denka Company Limited
Silane coupling agent: γ-Glycidoxytriethoxyxysilane “KBM-403”, manufactured by Shin-Etsu Chemical Co., Ltd.
Carnauba wax: “PEARL WAX No. 1-P”, manufactured by Denka Company Limited

### <Measurement of Fluidity>

The above-obtained curable resin composition was injected into a mold for test, and a spiral flow value was measured under conditions at 175° C. and at 70 kg/cm² for 120 seconds. The results are shown in Table 1.

Then, the above-obtained curable resin composition was pulverized, and the resultant material was molded into a shape of ϕ50 mm×3 (t) mm disc using a transfer molding machine at a pressure of 70 kg/cm² and at a temperature of 175° C. for a time period of 180 seconds, and further cured at 180° C. for 5 hours.

### <Measurement of Heat Resistance>

The cured product of the molded article produced above having a thickness of 0.8 mm was cut into a size of 5 mm width and 54 mm length to prepare a test piece 1. The test piece 1 was evaluated for glass transition temperature, by using a viscoelasticity meter (DMA: solid viscoelasticity meter “RSAII”, manufactured by Rheometric, rectangular tension method: frequency 1 Hz, temperature raising rate 3° C./min), with the temperature at which change in viscoelasticity is maximum (the rate of change in tan δ is maximum) taken as the glass transition temperature. The results are shown in Table 1.

<Measurement of a Mass Loss Ratio after Allowed to Stand at High Temperature> Evaluation of High-Temperature Stability

A cured product having a thickness of 1.6 mm of the above-prepared molded article was cut into a size having a width of 5 mm and a length of 54 mm, and the resultant specimen was used as a test piece 2. The test piece 2 was maintained at 250° C. for 72 hours and then, a mass loss ratio compared to the initial mass was measured. The results are shown in Table 1.

TABLE 1

| | | | | | Comparative | Comparative |
|---|---|---|---|---|---|---|
| | | Example 4 | Example 5 | Example 6 | Example 1 | Example 2 |
| Epoxy | A-1 | 113 | | | | |
| resin | A-2 | | 112 | | | |
| | A-3 | | | 112 | | |
| | I | | | | 115 | |
| | A-4 | | | | | 118 |
| Curing | TD-2093Y | 76 | 77 | 77 | 74 | 71 |
| agent | | | | | | |

| | | | | | |
|---|---|---|---|---|---|
| TPP | 3 | 3 | 3 | 3 | 3 |
| Fused silica | 800 | 800 | 800 | 800 | 800 |
| Silane coupling | 3 | 3 | 3 | 3 | 3 |
| agent | | | | | |
| Carnauba wax | 2 | 2 | 2 | 2 | 2 |
| Carbon black | 3 | 3 | 3 | 3 | 3 |

Results of measurement

| | | | | | |
|---|---|---|---|---|---|
| Spiral flow value | 48 | 50 | 52 | 39 | 44 |
| (cm) | | | | | |
| Glass transition | 258 | 260 | 259 | 249 | 248 |
| temperature (° C.) | | | | | |
| Mass loss ratio | 0.3 | 0.3 | 0.3 | 0.6 | 0.5 |
| after allowed to | | | | | |
| stand at high | | | | | |
| temperature (%) | | | | | |

1. An epoxy resin which is represented by the following structural formula (1): 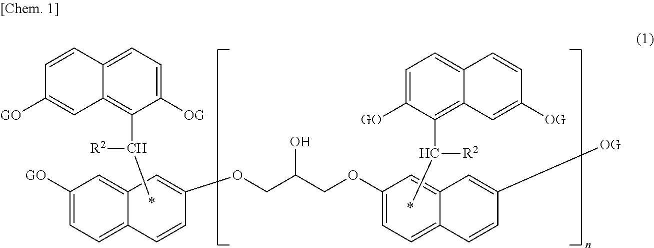
wherein G represents a glycidyl group, R¹ each independently represents a hydrogen atom, an alkyl group having 1 to 4 carbon atoms, a phenyl group, a hydroxyphenyl group, or a halogen-substituted phenyl group, symbol * indicates bonding to any of carbon atoms capable of forming a bond on the naphthalene ring, and n represents the number of repeats and is 0 to 10 on average, and which exhibits, in a GPC measurement, a peak P appearing between peaks with n=0 and n=1, wherein the area of the peak P is 0.0100 to 0.0750 times the area of the peak with n=0.

2. The epoxy resin according to claim 1, wherein, in the GPC measurement, the peak P appearing between the peaks with n=0 and n=1 has a peak area ratio of 0.5 to 4.5% by area.

3. The epoxy resin according to claim 1, which has an epoxy equivalent of 140 to 160 g/eq.

4. The epoxy resin according to claim 1, which has a melt viscosity of 1.0 to 3.5 dPa·s at 150° C. as measured in accordance with ASTM D4287.

5. A method for producing an epoxy resin, comprising: subjecting, to recrystallization, an epoxide of a phenol compound represented by the following structural formula (2): 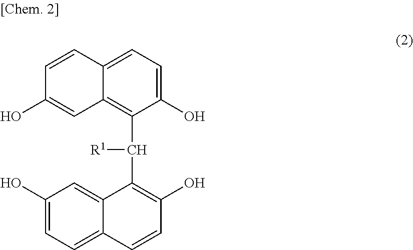
wherein R¹ each independently represents a hydrogen atom, an alkyl group having 1 to 4 carbon atoms, a phenyl group, a hydroxyphenyl group, or a halogen-substituted phenyl group.

6. A curable resin composition comprising: the epoxy resin according to claim 1; and a curing agent.

7. A cured product which is obtained by curing the curable resin composition according to claim 6.

8. A semiconductor encapsulating material comprising: the curable resin composition according to claim 6; and an inorganic filler.

9. A semiconductor device which is obtained by curing the semiconductor encapsulating material according to claim 8.

10. A prepreg which is a semi-cured product of an impregnated substrate comprising the curable resin composition according to claim 6 and a reinforcing substrate.

11. A method for producing a prepreg, the method comprising: impregnating a reinforcing substrate with a dilution prepared by diluting the curable resin composition according to claim 6 with an organic solvent; and semi-curing the resultant impregnated substrate.

12. A circuit board comprising: the curable resin composition according to claim 6 in the form of a plate; and a copper foil.

13. A method for producing a circuit board, the method comprising: diluting the curable resin composition according to claim 6 with an organic solvent to obtain a varnish; and subjecting, to heat-pressure molding, the varnish in the form of a plate and a copper foil.

14. An adhesive film for buildup, comprising: a dried coating film of the curable resin composition according to claim 6; and a substrate film.

15. A method for producing an adhesive film for buildup, the method comprising: applying, onto a substrate film, a dilution prepared diluting the curable resin composition according to claim 6 with an organic solvent; and drying the applied composition.

16. A buildup substrate comprising: a circuit board having a heat-cured product of the adhesive film for buildup according to claim 14; and a plating layer formed on the heat-cured product.

17. A method for producing a buildup substrate, the method comprising: applying the adhesive film for buildup according to claim 14 to a circuit board having a circuit formed; heat-curing the film; forming unevenness in the resultant circuit board; and then subjecting the circuit board to plating treatment.

18. A fiber-reinforced composite material comprising: the curable resin composition according to claim 6; and a reinforcing fiber.

19. A fiber-reinforced molded article which is obtained by curing the fiber-reinforced composite material according to claim 18.

20. A curable resin composition comprising: the epoxy resin according to claim 2; and a curing agent.
